(19) United States
(12) Patent Application Publication
(10) Pub. No.: US 2019/0320501 A1
(43) Pub. Date: Oct. 17, 2019

(54) ALL ALUMINUM HEATER

(71) Applicant: Watlow Electric Manufacturing Company, St. Louis, MO (US)

(72) Inventors: Patrick Margavio, Columbia, MO (US); Kurt English, Columbia, MO (US)

(73) Assignee: Watlow Electric Manufacturing Company, St. Louis, MO (US)

(21) Appl. No.: 16/386,870

(22) Filed: Apr. 17, 2019

Related U.S. Application Data
(60) Provisional application No. 62/658,768, filed on Apr. 17, 2018.

(51) Int. Cl. H05B 3/26

(52) U.S. Cl. CPC H05B 3/265; H01L 21/67103

(57) ABSTRACT

A heater includes a ceramic substrate and a heating layer made of aluminum material disposed in the ceramic substrate. The ceramic substrate includes a first plate member in which the heating layer is disposed and a second plate member through which a plurality of first vias made of the aluminum material extend. A routing layer made of the aluminum material can be disposed in the second plate member. The first plate member and the second plate member are bonded to each other by the aluminum material. The ceramic substrate can include a third plate member through which a plurality of second vias made from the aluminum material extend. The second plate member and the third plate member are bonded to each other by the aluminum material. Also, terminal wires can be bonded to the plurality of second vias.

### CROSS-REFERENCE TO RELATED APPLICATIONS

This application claims priority to U.S. provisional application No. 62/658,768 filed on Apr. 17, 2018. The disclosure of the above application is incorporated herein by reference.

### FIELD

The present disclosure relates generally to electric heaters, and more particularly to ceramic substrate heaters and methods of manufacturing the same.

### BACKGROUND

The statements in this section merely provide background information related to the present disclosure and may not constitute prior art.

A typical ceramic heater generally includes a ceramic substrate and a resistive heating element embedded within the ceramic substrate. Heat generated by the resistive heating element can be rapidly transferred to a heating target disposed proximate the ceramic substrate because of excellent heat conductivity of ceramic materials.

Ceramic materials, however, are known to be difficult to be bonded to metallic materials due to poor wettability of ceramic materials. Many of the ceramic materials and the metallic materials are non-wetting, making it difficult to cause a molten metal to flow into the pores of a ceramic material against capillary pressure to provide a good bonding therebetween. The bonding between the ceramic substrate and the resistive heating element may get worse when the coefficient of thermal expansion (CTE) of the resistive heating element is incompatible with the CTE of the ceramic substrate. Therefore, cracks or air gaps may be generated at the interface between the ceramic substrate and the resistive heating element, thereby adversely affecting the heat transfer from the resistive heating element through the ceramic material to the heating target.

The issues with forming a resistive heating element in a ceramic substrate, among other issues, are addressed by the present disclosure.

### SUMMARY

In one form of the present disclosure, a heater includes a ceramic substrate and a heating layer consisting of an aluminum material. In one variation, the heater includes a routing layer, a plurality of first vias connecting the heating layer to the routing layer, and the plurality of vias are made of the aluminum material. In some aspects, the heater includes the routing layer, the plurality of first vias connecting the heating layer to the routing layer, a plurality of second vias connecting the routing layer to a surface of the ceramic substrate, and the routing layer, the plurality of first vias and the plurality of second vias are made of an aluminum material. In one form, the ceramic substrate is made from aluminum nitride.

In some aspects of the present disclosure, the ceramic substrate includes a plurality of plate members that are bonded by the aluminum material. In at least one aspect, the plurality of plate members includes a first plate member, a second plate member through which a plurality of first vias extend, and the heating layer is disposed between the first plate member and the second plate member. Also, a routing layer can be disposed in the second plate member and in contact with the plurality of first vias and the surface of the plurality of plate members is between 100 nm and 5 μm. In at least one other aspect, the plurality of plate members includes a first plate member, a second plate member through which a plurality of first vias extend, and a third plate member through which a plurality of second vias extend. In some aspects the heating layer is disposed between the first plate member and the second plate member and terminal wires are bonded to the plurality of second vias. In at least one aspect, the routing layer is disposed between the second plate member and the third plate member and is in contact with the plurality of first vias and the plurality of second vias.

In another form of the present disclosure, a heater includes a ceramic substrate, a heating layer made from an aluminum material disposed in the ceramic substrate, and the ceramic substrate includes a plurality of plate members that are bonded by the aluminum material. In at least one aspect of the present disclosure, the ceramic substrate is made of aluminum nitride. In some aspects of the present disclosure, the plurality of plate members includes a first plate member in which the heating layer is disposed and a second plate member through which a plurality of first vias made from the aluminum material extend. In at least one aspect, the plurality of plate members includes a first plate member in which the heating layer is disposed, a second plate member through which a plurality of first vias made from the aluminum material extend, and a third plate member through which a plurality of second vias made from the aluminum material extend. In some aspects, a routing layer made from the aluminum material is disposed in the second plate member and is in contact with the plurality of first vias and the plurality of second vias.

In still another form of the present disclosure, a heater includes a ceramic substrate with a first plate member and a second plate member, a heating layer disposed in the first plate member, and a routing layer and a plurality of first vias disposed in the second plate member. The first plate member and the second plate member are made of aluminum nitride, and the heating layer, the routing layer and the plurality of first vias are made of an aluminum material. Also, the first plate member and the second plate member are bonded to each other by the aluminum material. In some aspects of the present disclosure, the ceramic substrate includes a third plate member through which a plurality of second vias made of the aluminum material extend and the third plate member is bonded to the second plate member by the aluminum material.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The present disclosure will become more fully understood from the detailed description and the accompanying drawings, wherein:

FIG. 1 is a cross-sectional view of a ceramic heater constructed in accordance with the teachings of the present disclosure;

FIG. 2 is a flow diagram of a method of manufacturing a ceramic heater in accordance with the teachings of the present disclosure;

FIG. 3A depicts a step of preparing a first plate member, a second plate member, and a third plate member with a first trench, first via holes, and second via holes, respectively, in accordance with the teachings of the present disclosure;

FIG. 3B depicts a step of bonding the second plate member to the first plate member in accordance with the teachings of the present disclosure;

FIG. 3C depicts a step of bonding a third plate member to the assembly of the first and second plate members in accordance with the teachings of the present disclosure;

FIG. 3D depicts a step of bonding termination wires to second vias in a third plate member in accordance with the teachings of the present disclosure; and

FIG. 4 is a perspective view of a variant of a first plate member with a plurality of heating layers and alignment holes and constructed in accordance with the teachings of the present disclosure.

Corresponding reference numerals indicate corresponding parts throughout the several views of the drawings.

### DETAILED DESCRIPTION

The following description is merely exemplary in nature and is not intended to limit the present disclosure, application, or uses.

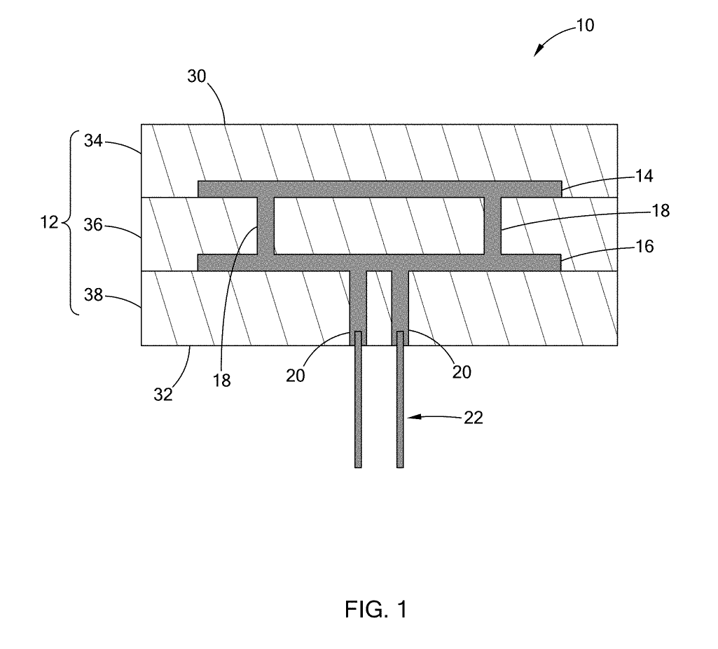

Referring to FIG. 1, a ceramic heater 10 constructed in accordance with the teachings of the present disclosure includes a substrate 12 made of ceramic materials, such as aluminum nitride (AlN), a heating layer 14 for generating heat, alternatively a routing layer 16, a plurality of first vias 18, and a plurality of second vias 20. When the routing layer 16 is included, the first vias 18 are disposed between the heating layer 14 and the routing layer 16 for connecting the heating layer 14 to the routing layer 16. Also, the second vias 20 are disposed under the routing layer 16 and in a central region of the substrate 12 for connecting the routing layer 16 to termination wires 22. The ceramic heater 10 may be used as a part of a support pedestal in semiconductor processing.

The substrate 12 has a flat plate configuration and defines an upper surface 30 for heating a heating target thereon and a bottom surface 32 from which terminal wires 22 extend. To form a support pedestal, a tubular shaft (not shown) may be bonded to the bottom surface 32 of the ceramic heater 10 and surround the termination wires 22. The substrate 12 may include a plurality of plate members 34, 36, 38. While three plate members 34, 36, 38 are shown in the illustrative example, the substrate 12 may include any number of plate members. The surface roughness of adjacent surfaces between the first and second plate members 34, 36 and between the second and third plate members 36, 38 are less than 5 μm, particularly between 100 nm and 5 μm.

The heating layer 14 is disposed between the first plate member 34 and the second plate member 36. In some aspects of the present disclosure, the heating layer 14 is disposed in the first plate member 34. That is, the heating layer 14 may be disposed on or partially in the first plate member 34 while remaining within the scope of the present disclosure. The routing layer 16 is disposed between the second plate member 36 and the third plate member 38. In some aspects, the routing layer 16 is disposed in the second plate member 36. That is, the routing layer 16 may be disposed on or partially in the second plate member 36 while remaining within the scope of the present disclosure. The first vias 18 are disposed in the second plate member 36. The third vias 20 are disposed in and extend through the third plate member 38. The heating layer 14, the routing layer 16, the first and second vias 18, 20 may be all made of aluminum material.

Alternatively, one or more of the heating layer 14, the routing layer 16, the first and second vias 18, 20 may be made of aluminum material, while the remaining one(s) may be made of other metallic materials without departing from the scope of the present disclosure. Also, the heating layer 14, the routing layer 16, the first vias 18 and/or the second vias 20 may be made from different aluminum materials (e.g., different aluminum alloys). When the heating layer 14, the routing layer 16, the first and second vias 18, 20 are all made of aluminum material, a hermetic bonding is formed between these layers/vias and the substrate 12, thereby eliminating the need for hermetic isolation, which would otherwise be required in a typical ceramic heater. Hermetic bonding created between the aluminum material and the ceramic material due to the use of the aluminum material will be described in more detail below.

Aluminum material has the desired temperature coefficient of resistance (TCR) to operate as a heating element at elevated temperature. TCR represents the property of a material that experiences an increase in electrical resistivity when the temperature is increased. Aluminum has resistivity at room temperature in the range of 2.65×10⁻⁸ to 5.9×10⁻⁸ Ω-m depending on the alloying composition (e.g. 5 nines purity, 7072, 6061, 5456, etc.), and has a TCR at 4290×10⁻⁶/° C. The resistivity of aluminum significantly increases at elevated temperature, making aluminum suitable for a heating element. Aluminum alloy, such as 5456 (AlMg5Mn1, A95456) aluminum, may be used over pure aluminum as the aluminum alloy has a higher room temperature resistivity and higher resistivity at elevated temperature.

The heating layer 14 may have a thickness between 5 and 200 μm. The routing layer 16 is made thicker than the heating layer 14 to concentrate heating in the heating layer 14 and reduce heating in the routing layer 16.

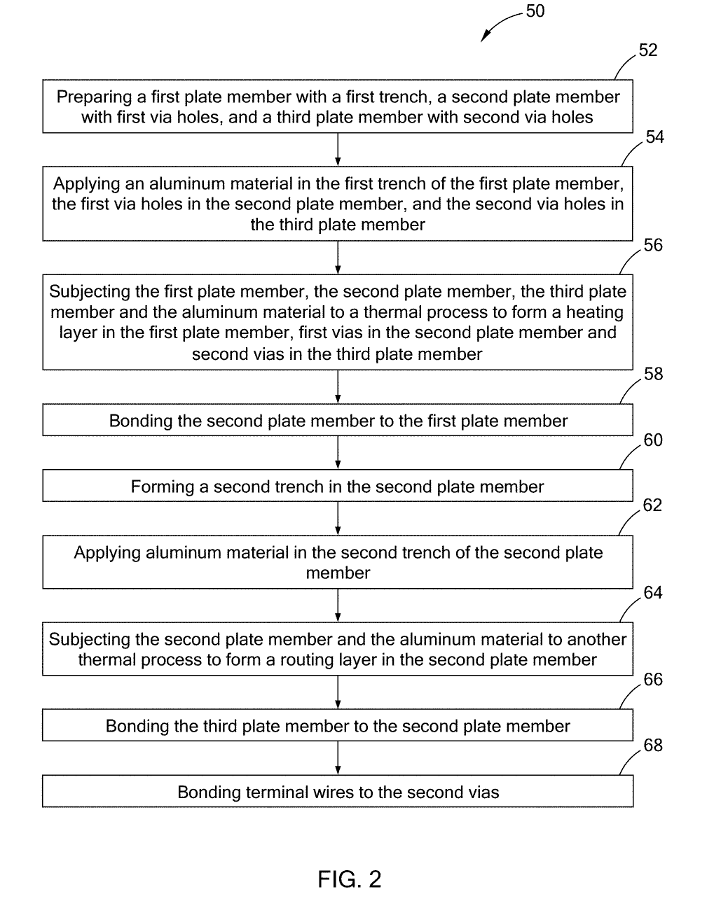

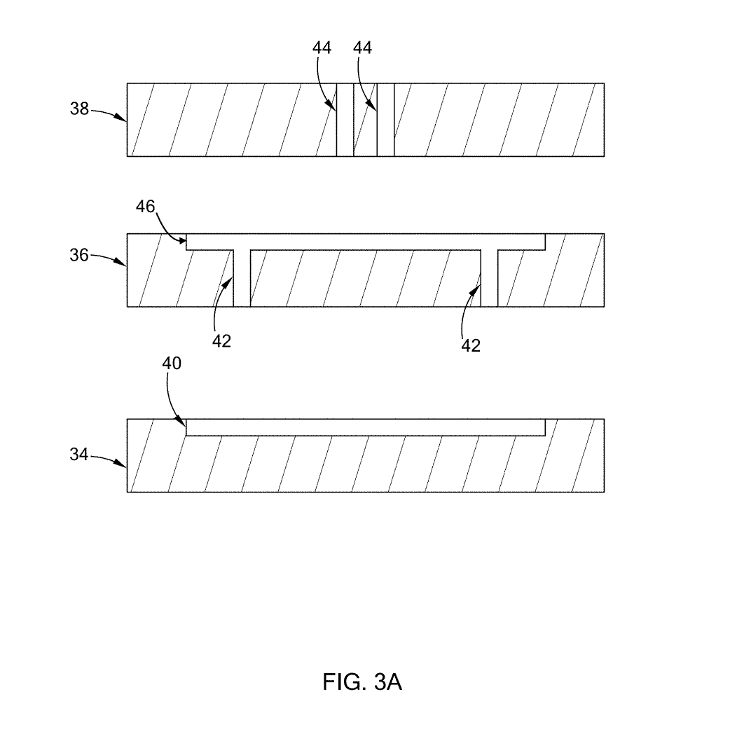

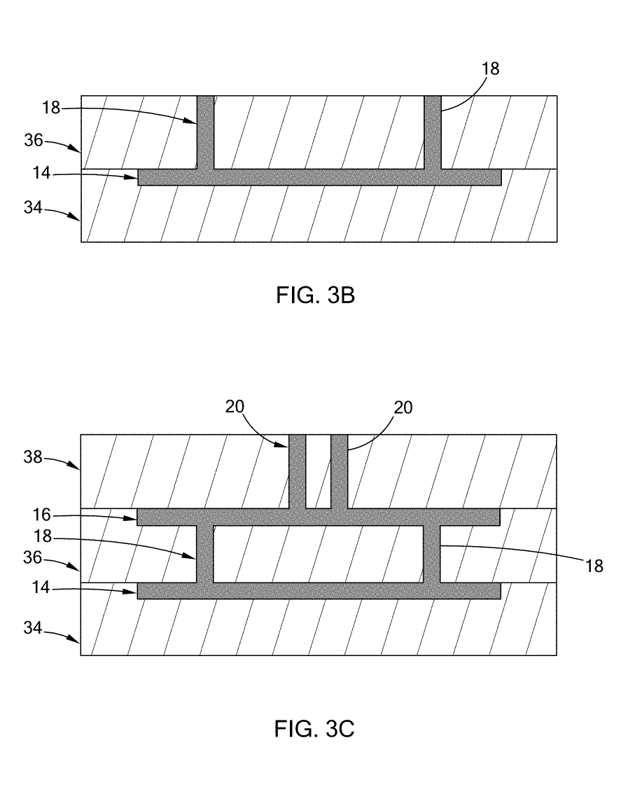

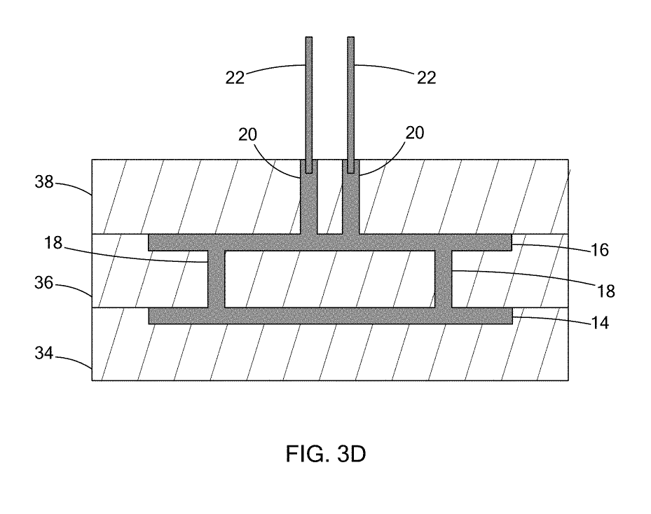

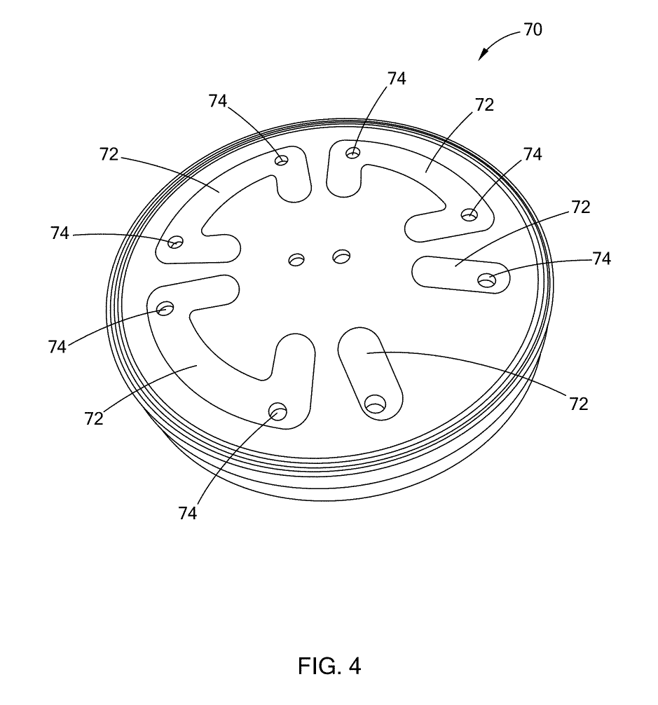

Referring to FIG. 2 and FIG. 3A, a method 50 of manufacturing a ceramic heater 10 starts with preparing a first plate member 34 with a first trench 40, a second plate member 36 with first via holes 42, and a third plate member 38 with second via holes 44 in step 52. In some aspects of the present disclosure, the second plate member 36 is formed with both the first via holes 42 and a second trench 46 in this step. The first trench 40 will be used to define a shape of the heating layer 14 and thus the geometry of the first trench 40 needs to be precisely controlled in order to provide a heating layer 14 with a predetermined thickness, which may be constant or varied. The first trench 40 may have a thickness in the range of 5 to 200 μm in order to form a heating layer 16 of the same thickness.

Next, an aluminum material is applied in the first trench 40 of the first plate member 34, the first via holes 42 of the second plate member 36, and the second via holes 44 of the third plate member 38 in step 54. In aspects of the present disclosure where the second plate member 36 is formed with both the first via holes 42 and the second trench 46 an aluminum material is also applied in the second trench 46. To apply the aluminum material in the first trench 40 and/or the second trench 46, the aluminum material may be in the form of an aluminum foil, aluminum powder, or any other solid form that can be placed in the first trench 40 and/or second trench 46. To apply the aluminum material in the first via holes 42 and the second via holes 44, the aluminum material may be in the form of aluminum rods that are inserted into the first and second via holes 42, 44. Alternatively, the aluminum material may be applied in the first trench 40, the second trench 46, the first via holes 42 and/or the second via holes 44 by applying an aluminum powder by sputtering, deposition, cold spray, cathodic arc deposition, or other thin film processes, among others. It should be understood that the aluminum material described herein does not necessarily have to be the same aluminum material for the heating layer 14, the vias 42, 44, and the routing layer 16 and that different aluminum materials/compositions may be used throughout each of these components while remaining within the scope of the present disclosure.

Thereafter, the first plate member 34, the second plate member 36, and the third plate member 38 are subjected to a thermal process to form the heating layer 14 in the first plate member 34, the first vias 18 through the second plate member 36, and the second vias 20 through the third plate member 38 in step 56. In aspects of the present disclosure where the second plate member 36 is formed with both the first via holes 42 and the second trench 46, the thermal process forms the routing layer 16 in the second plate member 36. The thermal process is performed at 660° C. to 1100° C. in a vacuum of between 1.33×10⁻³ Pa (10⁻⁵ Torr) and 1.33×10⁻⁵ Pa (10⁻⁷) Torr, or at a pressure of 0.1 to 6.4 MPa for a duration of approximately 10 to 90 minutes.

In the thermal process, the aluminum material is heated above a melting point of the aluminum material and is melted. Molten aluminum material has good wettability for bonding the aluminum compositions onto ceramic materials, particularly aluminum nitride (AlN). Therefore, the molten aluminum can completely fill in the first trench 40, the first via holes 42, and the second via holes 44 and conform to a geometry of the first trench 40, the first via holes 42, and the second via holes 44. Once the molten aluminum solidifies, the aluminum material is fully bonded to the wall of the first trench 40, and the walls of the first and second via holes 42, 44 so that a hermetic bonding is created between the aluminum material and the walls of the first trench 40, the walls of the first via holes 42, and the walls of the second via holes 44. The aluminum material in the first trench 40 forms the heating layer 14. The aluminum material in the first via holes 42 forms the first vias 18. The aluminum material in the second via holes 44 forms the second vias 20.

In addition to improved bonding with ceramic materials, using aluminum material to form the heating layer 14, the routing layer 16, and the first and second vias 18, 20 has the advantage of better controlling the resistance and geometry of the heating layer 14, the routing layer 16, the first and second vias 18, 20. In a typical via forming method using, for example, molybdenum thick film or molybdenum rods within an AlN ceramic, aluminide is generally formed during the bonding process. Therefore, it is difficult to determine and control the resistance and the geometry of the vias.

After the molten aluminum in the first trench 40 and in the first vias 18 solidifies, the second plate member 36 is bonded to the first plate member 34 in step 58. As shown in FIG. 3B, when the second plate member 36 is bonded to the first plate member 34, the first vias 18 are in contact with the heating layer 14.

To facilitate bonding between the first and second plates members 34 and 36, the first and second plate members 34 and 36 may optionally be configured to have at least one bonding trench (not shown) along a periphery of one or both of the first and second plate members 34 and 36 and at adjacent surfaces thereof. The bonding trench is filled with aluminum material that is used to bond the first and second plate members 34 and 36 together to provide additional hermetic bonding. The bonding trench has been described in co-pending U.S. application Ser. No. 15/955,431, titled “CERAMIC-ALUMINUM ASSEMBLY WITH BONDING TRENCHES,” which is commonly assigned with the present application, and the content of which is incorporated herein by reference in its entirety.

To use the aluminum material and a bonding trench to bond the first and second plate members 34, 36, a spacing between the first plate member 34 and the second plate member 36 along the adjacent surfaces is less than 5 μm. The first and second plate members 34, 36 are brought together to contact a solid aluminum material. A force and heat is applied to the assembly above a melting point of the solid aluminum material such that the solid aluminum material flows into the bonding trench. Additional heat is applied to the assembly at or above a wetting temperature of the first plate member 34 or the second plate member 36 in which the bonding trench is formed to bond the first plate member 34 to the second plate member 36. After the assembly is cooled, the molten aluminum solidifies and bonds the first and second plate members 34, 36 together to provide a hermetic bonding therebetween.

In some aspects of the present disclosure, the second plate member 36 is formed with the second trench 46 after the second plate member 36 is bonded to the first plate member 34 at step 60. An aluminum material is then applied in the second trench 46 of the second plate member in step 62. Similarly, the second plate member 36 and the aluminum material are subjected to another thermal process to form a routing layer 16 in the second trench 46 of the second plate member 36 in step 64. This thermal process is similar to that described in step 56.

Next, the third plate member 38 is bonded to the second plate member 36 in step 66. As shown in FIG. 3C, the second vias 20 of the third plate member 38 are in contact with the routing layer 16 in the second plate member 36. Finally, terminal wires 22 are bonded to the second vias 20 of the third plate member 38 in step 68, as shown in FIG. 3D. The termination wires 22 may be bonded to the second vias 20 metallurgically by brazing or welding the termination wires 22 to the second vias 20 or mechanically by tapping the aluminum filled via holes.

Alternatively, and as described above, the second plate member 36 may be formed with the first via holes 42 and the second trench 46 in step 52 before the aluminum material is applied. The aluminum material may be applied in the first via holes 42 and the second trench 46 simultaneously and the entire assembly is subjected to a thermal process.

Referring to FIG. 4, a variant of a first plate member 70 is shown to include a plurality of heating layers 72 and a plurality of alignment holes 74 for positioning aluminum rods, or aluminum material, that are/is to be inserted to connect the heating layers 72 to corresponding routing layers.

In the ceramic heater of the present disclosure, the heating layer is made of aluminum or aluminum alloy, which is not typically used as a heating element due to its poor mechanical properties at elevated temperatures and due to its significantly different CTE from that of the ceramic material. Typically, metals or metal alloys, such as molybdenum or tungsten, which have CTE matched to that of the AlN, are used to form the various functional layers in the ceramic substrate made of AlN to avoid thermal stress between the metals and the ceramic substrate at elevated temperatures. Typically, a metallic material with relatively low TCR is used to better control the resistance of the materials.

However, in the ceramic heater of the present disclosure, the ceramic heater leverages the properties of aluminum material in a way that is unique to the AlN—Al bonded system. Despite the incompatible CTE between aluminum and AlN, the wetting of the aluminum material to the ceramic substrate creates a good bonding therebetween, reducing the likelihood of generating cracks at their interface due to thermal stress. Accordingly, in one form of the present disclosure, the aluminum material (e.g., the aluminum heating layer) is bonded directly to the ceramic, without the use and/or presence of a separate bonding layer between the aluminum material and the ceramic substrate. The ceramic heater of the present disclosure also takes advantage of the high TCR of the aluminum material, which is typically not desirable in a heating element, and uses the aluminum material to form the heating layer. The resistance of the heating layer made of aluminum material may be closely monitored and controlled by using the teachings of U.S. Pat. No. 9,123,755 and its related family of applications, which are commonly owned with the present application and are incorporated by reference herein in their entirety.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above or below. The device may be otherwise oriented (rotated 90 degrees or at other orientations) and the spatially relative descriptors used herein interpreted accordingly.

Unless otherwise expressly indicated, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, manufacturing technology, and testing capability.

The terminology used herein is for the purpose of describing particular example forms only and is not intended to be limiting. The singular forms “a,” “an,” and “the” may be intended to include the plural forms as well, unless the context clearly indicates otherwise. The terms “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

The description of the disclosure is merely exemplary in nature and, thus, examples that do not depart from the substance of the disclosure are intended to be within the scope of the disclosure. Such examples are not to be regarded as a departure from the spirit and scope of the disclosure. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A heater comprising:
a ceramic substrate; and
a heating layer consisting of an aluminum material.

2. The heater according to claim 1, further comprising a routing layer, and a plurality of first vias connecting the heating layer to the routing layer.

3. The heater according to claim 2, wherein the routing layer and the plurality of first vias are made of the aluminum material.

4. The heater according to claim 2, further comprising a plurality of second vias connecting the routing layer to a surface of the ceramic substrate, the plurality of second vias being made of the aluminum material.

5. The heater according to claim 1, wherein the ceramic substrate is made of aluminum nitride (AlN).

6. The heater according to claim 1, wherein the ceramic substrate includes a plurality of plate members that are bonded by the aluminum material.

7. The heater according to claim 6, wherein the plurality of plate members includes a first plate member, a second plate member through which a plurality of first vias extend, and the heating layer is disposed between the first plate member and the second plate member.

8. The heater according to claim 7, further comprising a routing layer disposed between the second plate member and a third plate member and in contact with the plurality of first vias.

9. The heater according to claim 6, wherein a surface roughness of adjacent surfaces of the plurality of plate members is between 100 nm and 5 μm.

10. The heater according to claim 6, wherein the plurality of plate members includes a first plate member, a second plate member through which a plurality of first vias extend, a third plate member through which a plurality of second vias extend, and the heating layer is disposed between the first plate member and the second plate member.

11. The heater according to claim 10 further comprising terminal wires bonded to the plurality of second vias.

12. The heater according to claim 10, further comprising a routing layer disposed between the second plate member and the third plate member and in contact with the plurality of first vias and the plurality of second vias.

13. The heater according to claim 12 further comprising terminal wires bonded to the plurality of second vias.

14. A heater comprising:
a ceramic substrate; and
a heating layer consisting of an aluminum material disposed in the ceramic substrate, wherein the ceramic substrate includes a plurality of plate members that are bonded together by the aluminum material.

15. The heater according to claim 14, wherein the ceramic substrate is made of aluminum nitride (AlN).

16. The heater according to claim 14, wherein the plurality of plate members includes a first plate member in which the heating layer is disposed and a second plate member through which a plurality of first vias consisting of aluminum material extend.

17. The heater according to claim 14, wherein the plurality of plate members includes a first plate member in which the heating layer is disposed, a second plate member through which a plurality of first vias consisting of aluminum material extend, and a third plate member through which a plurality of second vias consisting of aluminum material extend.

18. The heater according to claim 17, further comprising a routing layer consisting of aluminum material disposed in the second plate member and in contact with the plurality of first vias and the plurality of second vias.

19. A heater comprising:
a ceramic substrate including a first plate member and a second plate member;
a heating layer disposed in the first plate member;
a routing layer and a plurality of first vias disposed in the second plate member;
wherein the first plate member and the second plate member are made of aluminum nitride, the heating layer, the routing layer and the plurality of first vias are made of an aluminum material, and the first plate member and the second plate member are bonded together by the aluminum material.

20. The heater according to claim 19, wherein the ceramic substrate further comprises a third plate member through which a plurality of second vias consisting of aluminum material extend and the third plate member is bonded to the second plate member by the aluminum material in the plurality of second vias.
